(19) United States
(12) Patent Application Publication
(10) Pub. No.: US 2006/0049855 A1
(43) Pub. Date: Mar. 9, 2006

(54) Integrated circuit

(75) Inventor: Jun Ikeda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/265,087

(22) Filed: Nov. 3, 2005

(30) Foreign Application Priority Data
May 11, 2004 (JP) 2004-322330

(51) Int. Cl. H03K 5/22

(52) U.S. Cl. 327/77

(57) ABSTRACT

A comparator circuit has a comparator comparing voltages supplied to a first and a second input terminal and outputting a comparison result signal corresponding to a comparison result, an input switch receiving a reference voltage and an input voltage and supplying the reference voltage to one of the first and the second input terminal while supplying the input voltage to another one of the first and the second input terminal according to a switching signal, an output inverting/noninverting circuit outputting the comparison result signal after inverting or not inverting the signal according to the switching signal, and a controller outputting the switching signal according to an operating condition of the comparator.

### BACKGROUND OF THE INVENTION

1. Field of the Invention

The present invention relates to integrated circuits and, particularly, to a comparator circuit that has a pair of transistors as inputs.

2. Description of the Related Art

An integrated circuit often has a comparator for comparing an input signal with a reference voltage. FIG. 10 is a block diagram showing input and output of a typical comparator 100. As shown in FIG. 10, the comparator 100 receives a reference voltage Vref that serves as a reference for comparison at its inverting input terminal and receives a changing signal such as an analog signal Ain to be compared at its noninverting input terminal. The comparator 100 outputs a comparison result signal Out that indicates a comparison result from its output terminal. Such a comparator normally uses a pair of transistors with the same characteristics in its input stage.

FIG. 11 is a circuit diagram showing an example of the input stage of the comparator 100 using a differential amplifier. In this circuit, an input signal Ain and a reference signal Vref are supplied to the gates of a pair of transistors N1 and N2, respectively, that are connected to a constant current source. The differential amplifier changes its output Vout according to the value of the input signal Ain. The comparison result signal Out of the comparator 100 is generated based on the output Vout.

In order that the comparator 100 having such an input stage operates normally, the characteristics of the transistors N1 and N2 in the input stage are preferably exactly the same. Therefore, transistors that are formed in the same process during fabrication of an integrated circuit are used as the transistors N1 and N2 in the input stage. Use of a pair of transistors with the same characteristics as an input section allows accurate comparison. Japanese Unexamined Patent Publication No. 05-14073 describes a technique about such a comparator.

However, even if a pair of transistors have the same characteristics immediately after the fabrication of an integrated circuit, a difference in the characteristic appears as the circuit operation progresses.

In the example of the transistors in the input stage shown in FIG. 11, the gate of the transistor N2 receives a constantly fixed reference voltage Vref. On the other hand, the gate of the transistor N1 receives a changing input signal Ain such as an analog signal. Due to a difference in signals supplied to the two transistors, the operating conditions differ between the transistors N1 and N2. Using the circuit of FIG. 11 with different operating conditions causes a difference to appear between the characteristics of the transistors N1 and N2. A difference in the characteristics of the transistors N1 and N2 leads to an error in comparison or other operations, which hinders that the comparator 100 maintains accurate operation.

A comparator is often used in an A/D converter or a D/A converter. Japanese Unexamined Patent Publication No. 05-24400, 2004-221720 and 2004-222227 describe a technique about such a converter. Using such a comparator also hinders that the converters maintains accurate operation.

As described above, the present invention has recognized that in the comparator using a differential input stage or the like the characteristics of the transistors for input change with time, which makes it difficult for the comparator 100 to maintain accurate operation.

### SUMMARY OF THE INVENTION

According to an aspect of the present invention, there is provided a comparator circuit that includes a comparator comparing voltages supplied to a first and a second input terminal and outputting a comparison result signal corresponding to a comparison result, an input switch receiving a reference voltage and an input voltage and supplying the reference voltage to one of the first and the second input terminal while supplying the input voltage to another one of the first and the second input terminal according to a switching signal, an output inverting/noninverting circuit outputting the comparison result signal after inverting or not inverting the signal according to the switching signal, and a controller outputting the switching signal according to an operating condition of the comparator.

This configuration prevents the appearance of a difference in the characteristics of the transistors used for input of the comparators.

According to yet another aspect of the present invention, there is provided a comparator circuit that includes a comparator comparing voltages supplied to a first and a second input terminal and outputting a comparison result signal corresponding to a comparison result, an input switch receiving a reference voltage and an input voltage and connecting the reference voltage to one of the first and the second input terminal while connecting the input voltage to another one of the first and the second input terminal according to a switching signal, an output inverting/noninverting circuit outputting the comparison result signal after inverting or not inverting the signal according to the switching signal, a counter counting the number of activation times of the comparator and outputting a switching request signal according to the number of activation times, a timer measuring an operating time of the comparator and outputting the switching request signal according to the operating time, and a switching signal generator outputting the switching signal according to the switching request signal.

This configuration prevents variation in characteristics of the transistors in an input section by executing switching based on both the number of activation times and the operating time.

According to still another aspect of the present invention, there is provided a comparator circuit that includes a comparator comparing voltages supplied to a first and a second input terminal and outputting a comparison result signal corresponding to a comparison result, an input switch receiving a reference voltage and an input voltage and supplying the reference voltage to one of the first and the second input terminal while supplying the input voltage to another one of the first and the second input terminal according to a switching signal, an output inverting/noninverting circuit outputting the comparison result signal after inverting or not inverting the signal according to the switching signal, a timer measuring an operating time of the comparator and outputting the switching signal according to a first predetermined time period and a second predetermined time period, and an offset detector detecting an offset of the comparator and setting the first predetermined time period and the second predetermined time period.

This configuration prevents the appearance of a difference in the transistors used for input of the comparator after improving offset.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a comparator circuit according to a first embodiment of the invention;

FIG. 2 is a circuit diagram showing the configuration of an input stage of the comparator circuit according to the first embodiment of the invention;

FIG. 3 is a view showing a difference in threshold voltage with respect to time;

FIG. 4 is a block diagram showing a comparator circuit according to a second embodiment of the invention;

FIG. 5 is a block diagram showing a comparator circuit according to a third embodiment of the invention;

FIG. 6 is a block diagram showing a comparator circuit according to a fourth embodiment of the invention;

FIG. 7 is a view showing improvement in offset according to the fourth embodiment;

FIG. 8 is a view showing a case where the comparator circuit of the embodiment is used for an A/D converter;

FIG. 9 is a view showing a case where the comparator circuit of the embodiment is used for a D/A converter;

FIG. 10 is a view showing a conventional comparator; and

FIG. 11 is a circuit diagram showing the configuration of an input stage of a conventional comparator.

### PREFERRED EMBODIMENT OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

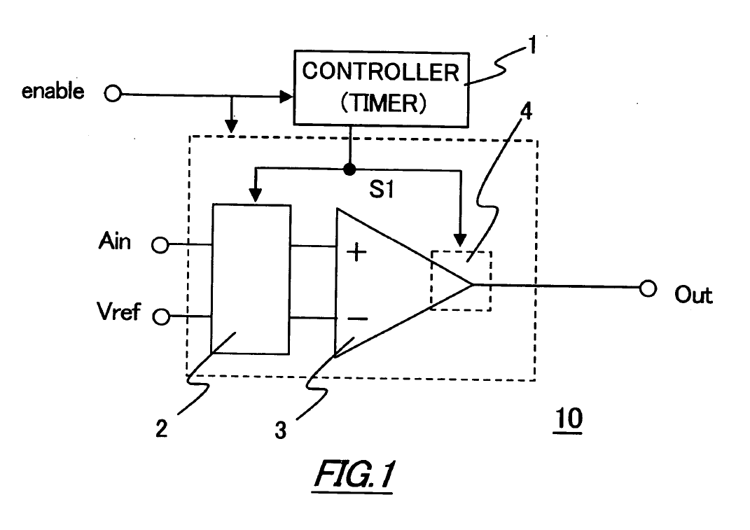

FIG. 1 is a block diagram showing a brief overview of a comparator circuit 10 according to a first embodiment of the invention. The comparator circuit 10 of the first embodiment has a timer 1, an input switch 2, a comparator 3, and an output inverting/noninverting circuit 4.

The timer 1 measures the operating time of the comparator circuit 10. The timer 1 outputs a switching signal S1 of a first logic level (for example, “L” level) or a second logic level (for example, “H” level) according to the operating time of the comparator circuit 10. That is, the timer 1 controls the operation of the comparator circuit 10.

The input switch 2 connects each of an input signal Ain, such as an analog input voltage, and a reference voltage Vref to an inverting input terminal (first input terminal) or a noninverting input terminal (second input terminal) of the comparator 3. The input switch 2 operates in accordance with the switching signal S1 that is supplied from the timer 1. For example, if the switching signal S1 is at “L” level, the input switch 2 supplies the reference voltage Vref to the inverting input terminal of the comparator 3 and supplies the input signal Ain to the noninverting input terminal of the comparator 3. On the other hand, if the switching signal S1 is at “H” level, the input switch 2 supplies the reference voltage Vref to the noninverting input terminal of the comparator 3 and supplies the input signal Ain to the inverting input terminal of the comparator 3.

The comparator 3 has an input transistor in each of its inverting input terminal and noninverting input terminal. The comparator 3 compares the voltage values input to the inverting input terminal and the noninverting input terminal and outputs a comparison result signal that corresponds to a comparison result.

The output inverting/noninverting circuit 4 selects whether to output the signal from the comparator 3 as it is or to output the signal after inverting it. The output inverting/noninverting circuit 4 operates in accordance with the switching signal S1 that is supplied from the timer 1. For example, if the switching signal S1 is at “L” level, the output inverting/noninverting circuit 4 outputs the output of the comparator 3 as it is. On the other hand, if the switching signal S1 is at “H” level, the output inverting/noninverting circuit 4 inverts the output of the comparator 3 and outputs the inverted signal.

The operation of the comparator circuit 10 shown in FIG. 1 is described below. The enable signal shown in FIG. 1 is ON when the comparator circuit 10 is active while it is OFF when the comparator circuit 10 is inactive. Thus, the enable signal may be a power-on signal of an apparatus or a signal supplied from another controller circuit.

If the enable signal turns ON, the comparator circuit 10 starts operating and the timer 1 starts measuring the operating time of the comparator circuit 10. The switching signal S1 that is output from the timer 1 in the initial state is at “L” level, for example. Receiving the switching signal S1, the input switch 2 supplies the input signal Ain to the noninverting input terminal of the comparator 3 and supplies the reference voltage Vref to the inverting input terminal of the comparator 3. Then, the output inverting/noninverting circuit 4 outputs the output of the comparator 3 as it is.

If the enable signal turns OFF before the total operating time measured by the timer 1 reaches a predetermined value, the timer 1 stores the operating time of the comparator circuit 10 into a register or the like, which is not shown, and stops operating.

The timer 1 measures the operating time every time the comparator circuit 10 is activated and calculates the total operating time. If the total operating time of the comparator circuit 10 reaches a predetermined value, the timer 1 changes the switching signal S1 to “H” level, for example. Given this change in the switching signal S1, the input switch 2 supplies the reference voltage Vref to the noninverting input terminal of the comparator 3 and supplies the input signal Ain to the inverting input terminal of the comparator 3. Then, the output inverting/noninverting circuit 4 outputs an inverted signal of a comparison result signal of the comparator 3. As described above, the timer operates as a controller to control the comparator circuit 10 according to an operating condition of the comparator circuit.

As described above, the reference voltage Vref and the input signal Ain to be connected to the inverting input terminal and the noninverting input terminal of the comparator 3 are switched depending on the operating time of the comparator circuit 10. Further, the output inverting/noninverting circuit 4 switches whether to output the comparison result signal as it is or after inverting it. The transistor to receive the input signal Ain is thereby switched. This prevents that the characteristics of the transistors connected to the first and second input terminals become different from each other because of a changing signal supplied to one transistor only. This switching may be performed a plurality of times at every predetermined time interval. Performing the switching operation at every predetermined time interval effectively prevents a difference from occurring in the characteristics of the transistors used for input of the comparator 3.

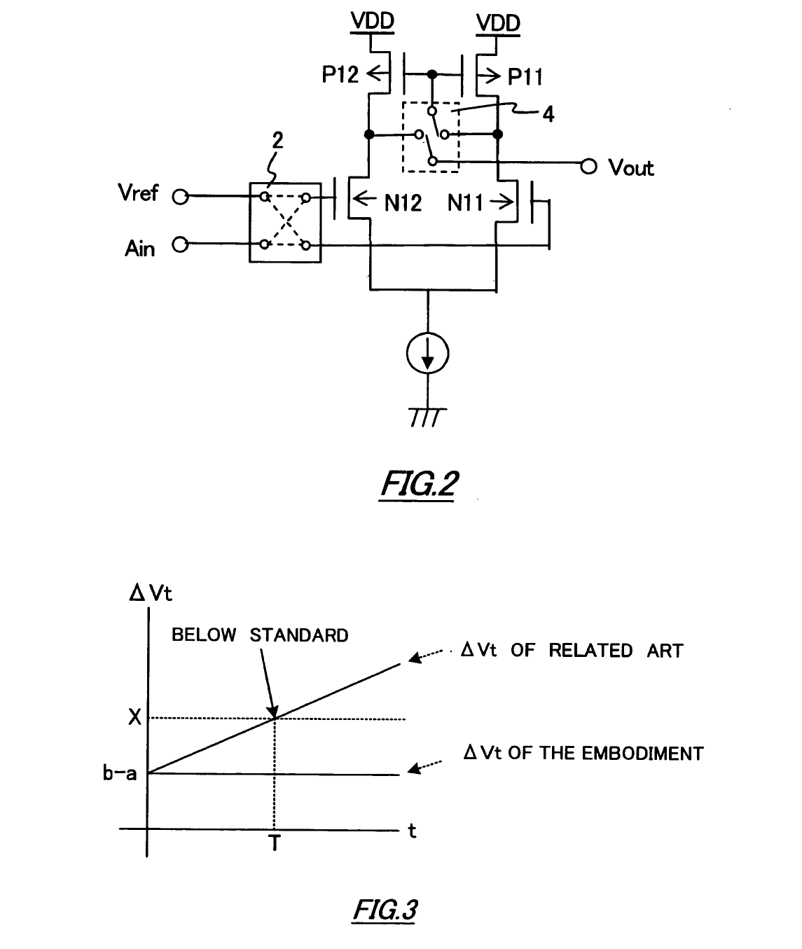

FIG. 2 is a pattern diagram showing the configuration of the input stage of the comparator 3 according to this embodiment. This input stage is implemented by a differential stage, having first to fourth MOS transistors P11, P12, N11, and N12. The first MOS transistor P11 and the second MOS transistor P12 are P-type MOS transistors. The sources of the first and second transistors P11 and P12 are connected to power supply voltage VDD. The drain of the first transistor P11 is connected to the drain of the third transistor N11. The drain of the second transistor P12 is connected to the drain of the fourth transistor N12. The third transistor N11 and the fourth transistor N12 are N-type transistors. The sources of the third and fourth transistors N11 and N12 are grounded through a constant current source.

The input switch 2 and the output inverting/noninverting circuit 4 may be implemented by a switch or the like that operate in accordance with the switching signal S1. For example, when the switching signal S1 is at “L” level, the input switch 2 supplies the reference voltage Vref to the gate of the fourth transistor N12 and supplies the input signal Ain to the gate of the third transistor N11. At this time, the output inverting/noninverting circuit 4 connects the gates of the first and second transistors P11 and P12 to the drain of the second transistor P12 so as to form a current mirror. Further, the output inverting/noninverting circuit 4 connects the output terminal to the drain of the first transistor P11.

When the switching signal S1 turns to “H” level, the above connections are reversed. Specifically, the input switch 2 supplies the reference voltage Vref to the gate of the third transistor N11 and supplies the input signal Ain to the gate of the fourth transistor N12. At this time, the output inverting/noninverting circuit 4 connects the gates of the first and second transistors P11 and P12 to the drain of the first transistor P11 so as to form a current mirror. Further, the output inverting/noninverting circuit 4 connects the output terminal to the drain of the second transistor P12. This configuration allows switching the transistor to receive the input signal Ain at every predetermined timer interval.

In the following, a change of the circuit characteristics in the configuration that switches the signals supplied to the gates of the transistors N11 and N12 in the input stage is described.

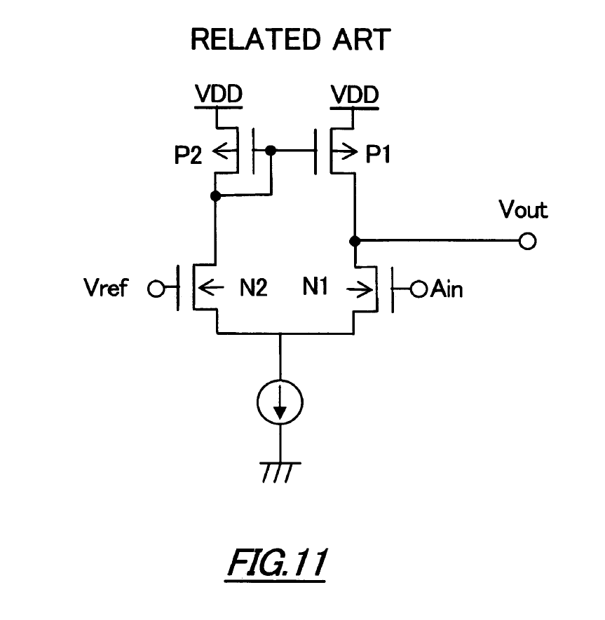

A designed threshold voltage of the transistors N1 and N2 of a conventional circuit shown in FIG. 11 is represented by Vt0. An offset from a design value of the transistor N1 immediately after fabrication is represented by “a” and an offset of the transistor N2 is represented by “b”. Further, a rate of change in threshold voltage of the transistor N1 receiving the input signal Ain is represented by “A”. The rate of change in threshold voltage indicates a rate that a threshold voltage changes per unit of time when the input signal Ain is supplied to the transistor.

The transistor N2 of the circuit shown in FIG. 11 receives the reference voltage Vref, and a rate of change in threshold voltage is represented by “B”. If the threshold voltages of the transistors N1 and N2 at time t are Vt1(t) and Vt2(t), respectively, and a difference in threshold voltage between the transistors N1 and N2 is ΔVt(t), each value is expressed as follows:
V₁₁(t)=Vt₀+a+At
Vt₂(t)=Vt₀+b+Bt
ΔVt(t)=(b−a)+(B−A)t

If the circuit characteristics are below standard when ΔVt(t)=X, a time T when the circuit characteristics fall below standard is defined by the following expression:

$$T = \frac{X - ( b - a )}{B - A}$$

By sufficiently reducing the value of (b−a) during design time, it is possible to extend the operating time until the circuit characteristics fall below standard in design to some extent. However, a conventional comparator can hardly maintain the circuit characteristics beyond a predetermined time period even when the value of (b−a) is 0.

On the other hand, the characteristics change as follows if input is switched as in the comparator circuit 10 of this embodiment. In the following calculation, it is assumed that duty of “H” level and “L” level period of the switching signal S1 is 50%, that is, the time period to receive the input signal Ain is the same between the transistors N11 and N12. In this case, if the threshold voltages of the transistors N11 and N12 at time tare Vt11(t) and Vt12(t), respectively, and a difference in threshold voltage between the transistors N11 and N12 is ΔVt(t), each value is expressed as follows:

$${Vt}_{11} ( t ) = {Vt}_{0} + a + \frac{A}{2} t + \frac{B}{2} t$$

$${Vt}_{12} ( t ) = {Vt}_{0} + b + \frac{A}{2} t + \frac{B}{2} t$$

$$Δ Vt ( t ) = ( b - a )$$

FIG. 3 shows a change in ΔVt(t) with time in comparison with that in a conventional circuit shown in FIG. 11. As shown in FIG. 3, when using the comparator circuit 10 of this embodiment, the value of ΔVt(t) is determined only by the initial conditions in fabrication. The configuration of switching the transistor to receive the input signal Ain can prevent that a difference in characteristics between the third and fourth transistors N11 and N12 emerges as time progresses. This contributes to cost down by reduction of a circuit size.

Though the circuit diagram of FIG. 2 shows the output inverting/noninverting circuit 4 that changes over the output terminal with a switch, the output inverting/noninverting circuit 4 may have a different configuration as long as it can invert the output signal in response to the switching signal S1 based on the operating time.

The above description describes the operation that switches the input and output when the operating time passes beyond a predetermined time period. In this case, the input terminal and output can be switched while performing the comparing operation. To overcome this drawback, it is feasible to make a configuration that prevents the switching during comparison.

In this configuration, the timer 1 has a register for storing a switching flag or the like, for example. When the total operating time of the comparator circuit 10 exceeds a predetermined value during comparison, the timer 1 stores a switching flag into a register or the like in the timer 1. The timer 1 does not change the switching signal S1 while the enable signal is ON and the comparison is being performed. When the comparison ends and the enable signal turns OFF, the timer 1 changes the level of the switching signal S1 according to the switching flag. This configuration avoids that the switching of input and the inversion of output are performed in the course of comparison.

It is also feasible to make a configuration that outputs an error signal or the like to a circuit in the subsequence stage when the timer 1 performs switching. Receiving the error signal, the circuit in the subsequent stage stops the ongoing operation and restarts operation according to a comparison result. In this configuration, the switching operation does not affect the operation of the circuit in the subsequence stage even if it occurs during comparison.

### Second Embodiment

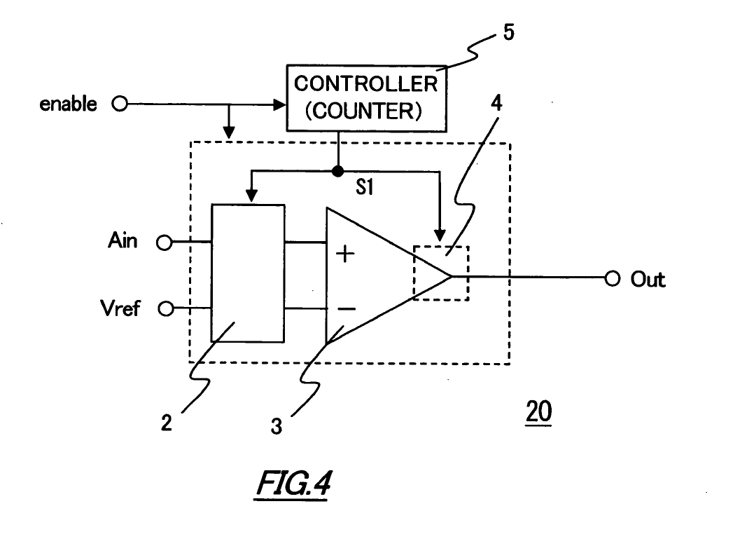

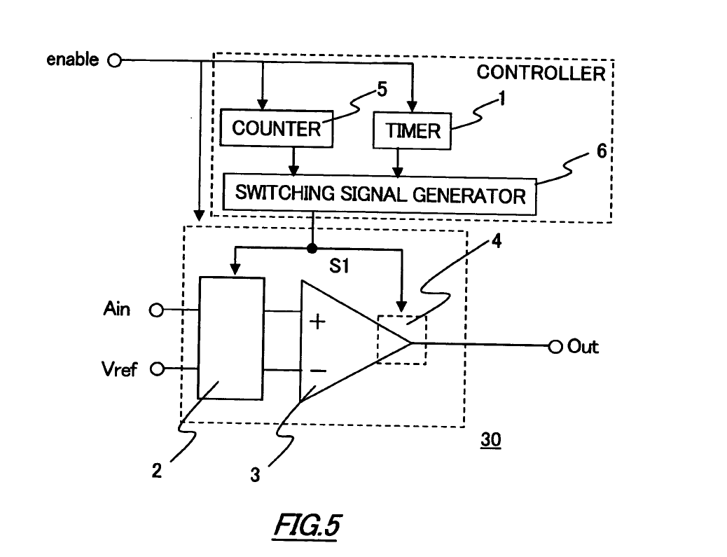

FIG. 4 is a block diagram showing a comparator circuit 20 according to a second embodiment of the present invention. The same elements as in the first embodiment are denoted by the same reference symbols and not described herein. The second embodiment uses a counter 5 instead of the timer 1 that is used in the first embodiment.

The counter 5 counts the number of times that the enable signal turns ON and changes the output level of the switching signal S1 according to the counted number of times.

The second embodiment counts the number of times that the comparator circuit 20 is activated (activation count) instead of the operating time that is measured in the first embodiment. When the number of times that the enable signal turns ON reaches a predetermined number of times, the counter 5 changes the level of the switching signal S1. This switching may be performed a plurality of times at every predetermined time interval as described in the first embodiment. As described above, the counter operates as a controller to control the comparator circuit 10 according to an operating condition of the comparator circuit.

This configuration performs switching immediately after the activation count reaches a predetermined value or when the enable signal turns OFF after the activation count reaches a predetermined value. The switching is thus not performed during comparison, thereby achieving stable operation.

### Third Embodiment

FIG. 5 is a block diagram showing a comparator circuit 30 according to a third embodiment of the present invention. The same elements as in the first and second embodiments are denoted by the same reference symbols and not described herein. The comparator circuit 30 of the third embodiment has the timer 1, the counter 5, and a switching signal generator 6. The counter 5 counts the number of times that the enable signal turns ON as described in the second embodiment. The counter 5 supplies a switching request signal to the switching signal generator 6 when the comparator circuit 30 is activated more than a predetermined number of times. The timer 1 measures the operating time of the comparator circuit 30 as in the first embodiment. The timer 1 supplies a switching request signal to the switching signal generator 6 when the comparator circuit 30 operates for longer than a predetermined time period.

In the third embodiment, the switching signal generator 6 generates a switching signal S1. The switching signal generator 6 changes the level of the switching signal S1 upon receiving the switching request signal from the counter 5 or the timer 1. As described above, the timer, the counter and the switching generator operate as the controller to control the comparator circuit 10 according to an operating condition of the comparator circuit.

This configuration allows changing the level of the switching signal if the comparator circuit 30 operates for longer than a predetermined time period even when it is not activated more than a predetermined number of times.

### Fourth Embodiment

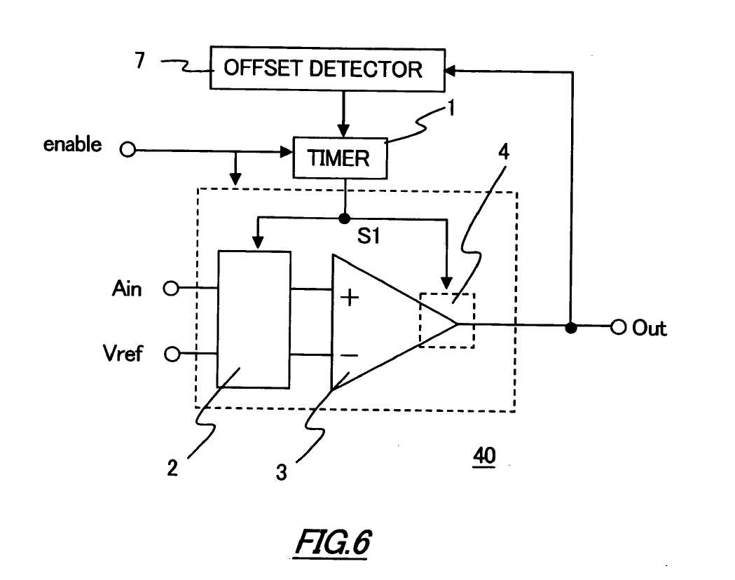

FIG. 6 is a block diagram showing the comparator circuit 40 of a fourth embodiment of the present invention. The same elements as in the first embodiment are denoted by the same reference symbols and not described herein. The timer 1 operates as the controller in this embodiment.

The comparator circuit 40 of the fourth embodiment has an offset detector 7 in addition to the configuration of the first embodiment 1. The offset detector 7 detects an offset from a design value of the transistor in the comparator 3 from the output of the comparator 3.

The timer (controller) 1 switches the level of a switching signal at every predetermined time interval as in the first embodiment. This embodiment, however, is different from the first embodiment in that the time when the timer 1 switches the level of a switching signal is determined by an offset value that is detected by the offset detector 7.

The operation of the circuit according to the fourth embodiment is described below. In this embodiment, the offset detector 7 detects an offset of the comparator 3 when the comparator circuit 40 starts operating. From the detected offset value, the offset detector 7 calculates first and second predetermined time periods for the timer 1 to change the level of the switching signal S1.

It is assumed that a time period to switch the switching signal from “L” to “H” is a first predetermined time period t1 and a time period to switch the switching signal from “H to “L” is a second predetermined time period t2. If the switching signal is at “L” level, the input signal Ain is supplied to the third transistor N11 and the reference voltage Vref is supplied to the fourth transistor N12. On the other hand, if the switching signal is at “H” level, the input signal Ain is supplied to the fourth transistor N12 and the reference voltage Vref is supplied to the third transistor N11.

Calculation of the threshold voltages of the transistors N11 and N12, ΔVt(t), by using the time periods t1 and t2 gives the following expressions:
Vt₁₁(t)=Vt₀+a+At1+Bt2
Vt₁₂(t)=Vt₀+b+At2+Bt1
ΔVt(t)=(b−a)+A(t2−t1)+B(t1−t2)

As obvious from the above expressions, a difference in threshold voltage of the transistors N11 and N12 changes in a different way depending on a difference between t1 and 2. Further, a way that a difference in threshold voltage of the transistors N11 and N12 changes (whether the changing direction of ΔVt is plus or minus) corresponds to the changing direction of an offset voltage of the comparator. Thus, the fourth embodiment measures an offset voltage of the comparator 3 and sets the values of t1 and t2 so as to improve the offset voltage of the comparator 3. For example, the offset detector 7 calculates a time period that improves the offset voltage of the comparator 3 together with the operation of the comparator circuit 40 by setting the first predetermined time period longer than the second predetermined time period, for example.

The timer 1 changes the level of the switching signal S1 according to the first and second predetermined time periods that are set by the offset detector 7.

In sum, the fourth embodiment changes the switching signal according to the predetermined time period that is set by the offset detector 7, thereby improving the offset of the comparator 3. This embodiment outputs a signal to equalize the first predetermined time period and the second predetermined time period to the timer 1 when the offset detector 7 detects no more offset. The timer 1 thereby sets the first predetermined time period and the second predetermined time period the same when no more offset is detected, and then changes the level of the switching signal so that a difference does not appear in a change of threshold voltages of the transistors N11 and N12 after that.

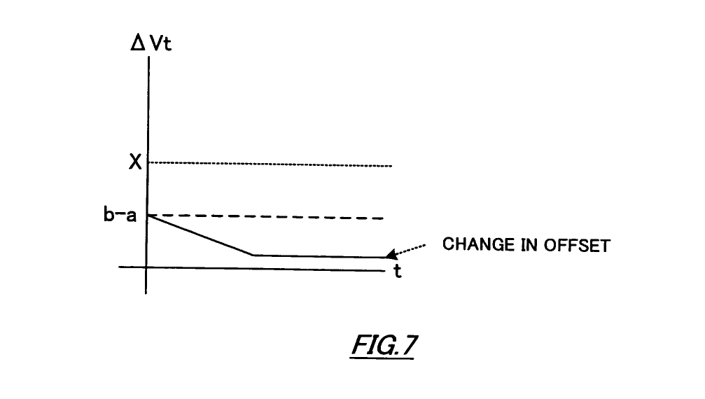

This configuration allows operating the comparator circuit 40 so as to prevent the appearance of a difference in the characteristics of the transistors in the input stage after improving an initial offset of the comparator 3. FIG. 7 shows a change in characteristics of the transistors due to this operation.

Though the fourth embodiment sets the first and second predetermined time periods by using the offset detector, it is feasible to apply the offset detector to the comparator circuit of the second or third embodiment.

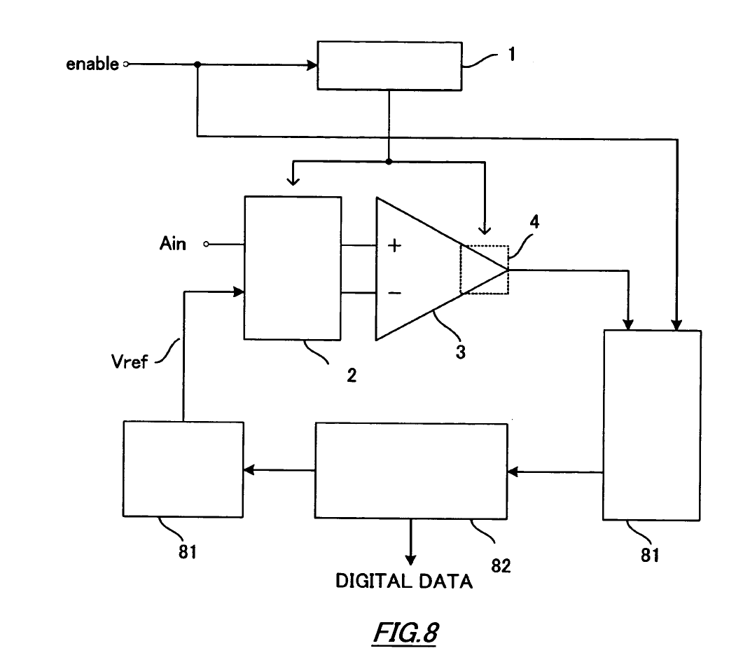

FIG. 8 shows a case where the comparator circuit described in the first to fourth embodiments is used in an A/D converter that converts an analog signal into a digital signal. In FIG. 8, the comparator circuit is applied to a successive approximation A/D converter, which is a circuit that sequentially compares input signals Ain and reference voltages Vref and outputs n-bit digital data. The successive approximation A/D converter compares the signals from a bit corresponding to the most significant bit (MSB) of digital data. A comparison result is sequentially stored into a successive approximation register 83 or the like through a controller 82. After the least significant bit (LSB) is determined, the data is output as digital output. In the successive approximation A/D conversion, a voltage that is generated by a D/A converter 81 based on the determined high-order bit is stored as a reference voltage in a comparator circuit. In such a case, it is possible to prevent a difference from occurring in the transistors in the input section of the comparator circuit by periodically switching between the input terminal of a reference voltage and the input terminal of an analog signal input terminal.

Though FIG. 8 applies the present invention to the comparator circuit used in the successive approximation A/D converter, it is also applicable to the comparator circuit in a flash A/D converter and a sample-and-hold circuit.

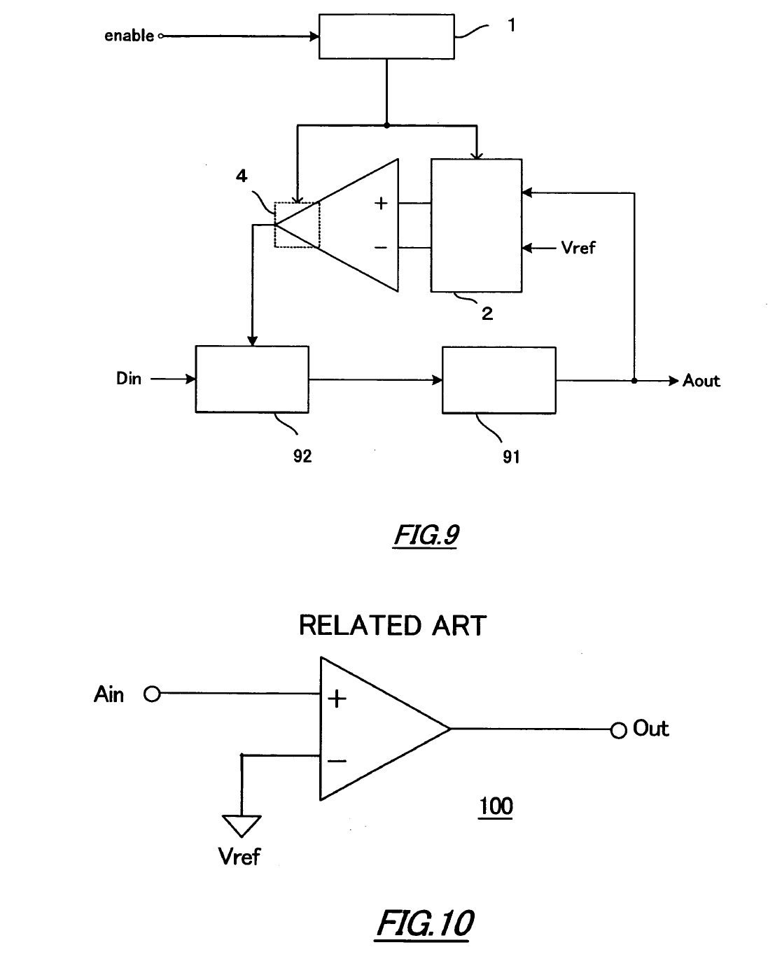

FIG. 9 shows a case where the comparator circuit described in the first to fourth embodiments is used in a D/A converter. The D/A converter shown in FIG. 9 compares the output of a D/A converter 91 with a given voltage value Vref in the comparator circuit, thereby correcting an offset of the D/A converter. A comparison result is supplied to an offset correction circuit 92 where the offset is corrected. By using such a D/A converter, it is possible to prevent that an error in offset correction value increases with time due to deterioration of a comparator, thereby allowing offset correction within a certain accuracy.

It is apparent that the present invention is not limited to the above embodiment that may be modified and changed without departing from the scope and spirit of the invention.

What is claimed is:

1. A comparator circuit comprising:
a comparator comparing voltages supplied to a first and a second input terminal and outputting a comparison result signal corresponding to a comparison result;
an input switch receiving a reference voltage and an input voltage and supplying the reference voltage to one of the first and the second input terminal while supplying the input voltage to another one of the first and the second input terminal according to a switching signal;
an output inverting/noninverting circuit outputting the comparison result signal after inverting or not inverting the signal according to the switching signal; and
a controller outputting the switching signal according to an operating condition of the comparator.

2. The comparator circuit according to claim 1, wherein the controller is a timer measuring an operating time of the comparator and outputting the switching signal according to the operating time.

3. The comparator circuit according to claim 2, wherein the timer changes the switching signal when the operating time reaches a predetermined time.

4. The comparator circuit according to claim 3, wherein the timer outputs an error signal in addition to changing the switching signal.

5. The comparator circuit according to claim 2, wherein when the operating time reaches a predetermined time, the timer stores information indicating that the predetermined time is reached, and when the comparator circuit stops operating after that, the timer changes the switching signal.

6. The comparator circuit according to claim 1, wherein the controller is a counter counting the number of activation times of the comparator and outputting the switching signal according to the number of activation times.

7. The comparator circuit according to claim 6, wherein the counter comprises a timer measuring an operating time of the comparator and outputting the switching signal according to the operating time, and a counter counting the number of activation times of the comparator and outputting the switching signal according to the number of activation times.

8. A comparator circuit comprising:
a comparator comparing voltages supplied to a first and a second input terminal and outputting a comparison result signal corresponding to a comparison result;
an input switch receiving a reference voltage and an input voltage and supplying the reference voltage to one of the first and the second input terminal while supplying the input voltage to another one of the first and the second input terminal according to a switching signal;
an output inverting/noninverting circuit outputting the comparison result signal after inverting or not inverting the signal according to the switching signal;
a timer measuring an operating time of the comparator and outputting the switching signal according to a first predetermined time period and a second predetermined time period; and
an offset detector detecting an offset of the comparator and setting the first predetermined time period and the second predetermined time period.

9. An A/D converter comprising the comparator circuit according to claim 1.

10. An A/D converter comprising the comparator circuit according to claim 6.

11. An A/D converter comprising the comparator circuit according to claim 8.

12. A D/A converter comprising the comparator circuit according to claim 1.

13. A D/A converter comprising the comparator circuit according to claim 6.

14. A D/A converter comprising the comparator circuit according to claim 8.
